(19) United States
(12) Patent Application Publication
(10) Pub. No.: US 2019/0229334 A1
(43) Pub. Date: Jul. 25, 2019

(54) POSITIVE ELECTRODE MATERIAL FOR SECONDARY BATTERIES, METHOD FOR PRODUCING THE SAME, AND LITHIUM-ION SECONDARY BATTERY

(71) Applicant: FUJITSU LIMITED, Kawasaki-shi (JP)

(72) Inventor: Tomochika KURITA, Kawasaki (JP)

(73) Assignee: FUJITSU LIMITED, Kawasaki-shi (JP)

(21) Appl. No.: 16/369,543

(22) Filed: Mar. 29, 2019

Related U.S. Application Data
(63) Continuation of application No. PCT/JP2016/080078, filed on Oct. 11, 2016.

(51) Int. Cl. H01M 4/58; H01M 10/0525; C30B 1/02; C30B 29/14; C01B 25/45

(52) U.S. Cl. CPC H01M 4/5825; H01M 10/0525; H01M 2004/028; C30B 29/14; C01B 25/45; C30B 1/02

(57) ABSTRACT

A positive electrode material for secondary batteries, the positive electrode material being represented by Li₄₊ₓFe_{4+y}(P₂O₇)₃, where −0.80≤x≤0.60, −0.30≤y≤0.40, and −0.30≤x+y≤0.30, the positive electrode material comprising a triclinic crystal structure.

### CROSS-REFERENCE TO RELATED APPLICATION

This application is a continuation application of International Application PCT/JP2016/080078 filed on Oct. 11, 2016 and designated the U.S., the entire contents of which are incorporated herein by reference.

### FIELD

The embodiment discussed herein is related to a positive electrode material for secondary batteries, a method for producing the positive electrode material for secondary batteries, and a lithium-ion secondary battery that includes the positive electrode material for secondary batteries.

### BACKGROUND

Secondary batteries having large energy densities have been used as storage batteries included in a mobile phone, a mobile personal computer, a sensing device, an electric vehicle, and the like. Examples of the secondary batteries include a lithium-ion secondary battery.

The lithium-ion secondary battery includes a positive electrode including a positive electrode active material that causes an oxidation-reduction reaction and a negative electrode including a negative electrode active material that causes an oxidation-reduction reaction. The positive electrode active material and the negative electrode active material release energy by causing the chemical reaction. The lithium-ion secondary battery serves as a battery by extracting the released energy as electric energy.

The power at which a sensing device or the like can be driven and the amount of time during which a sensing device or the like can be driven greatly vary with the energy density of a positive electrode material included in a battery. One of the methods for producing a positive electrode material having a high energy density is to use a positive electrode material having a high potential.

Examples of known positive electrode materials include LiCoO₂ (3.6 to 3.7 V), LiMn₂O₄ (3.7 to 3.8 V), and LiFePO₄ (3.3 to 3.4 V). Among these, LiCoO₂ and LiMn₂O₄ disadvantageously increase the cost of the positive electrode material since the raw materials, that is, cobalt (Co) and manganese (Mn), are expensive. On the other hand, LiFePO₄ does not significantly increase the cost of the positive electrode material since it is produced using iron, which is an inexpensive element, as a raw material. However, LiFePO₄ has a lower potential than LiCoO₂ or LiMn₂O₄.

Examples of the related art include Japanese Laid-open Patent Publication No. 2011-222498.

### SUMMARY

According to an aspect of the embodiments, a positive electrode material for secondary batteries, the positive electrode material being represented by Li₄₊ₓFe_{4+y}(P₂O₇)₃, where −0.80≤x≤0.60, −0.30≤y≤0.40, and −0.30≤x+y≤0.30, the positive electrode material comprising a triclinic crystal structure.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic cross-sectional view of a lithium-ion secondary battery;

FIG. 2 illustrates an XRD spectrum of the substance prepared in Example 1;

FIG. 3 illustrates diffraction peaks of the XRD spectrum illustrated in FIG. 2 which occur at lower angles;

FIGS. 4A and 4B schematically illustrate the crystal structure (triclinic) of the substance prepared in Example 1 as a principal product;

FIG. 5 illustrates XRD spectra determined when the Fe content is changed;

FIG. 6A illustrates the constant-current charge/discharge curve of a half cell including the positive electrode material prepared in Example 1; and

FIG. 6B illustrates a dQ/dV plot derived from the constant-current charge/discharge curve illustrated in FIG. 6A.

### DESCRIPTION OF EMBODIMENTS

The embodiment discussed herein provides an inexpensive positive electrode material for secondary batteries which has a potential comparable to that of LiCoO₂, a method for producing the positive electrode material for secondary batteries, and a lithium-ion secondary battery that includes the positive electrode material for secondary batteries.

According to an aspect, an inexpensive positive electrode material for secondary batteries which has a potential comparable to that of LiCoO₂ may be provided. According to another aspect, a method for producing the inexpensive positive electrode material for secondary batteries which has a potential comparable to that of LiCoO₂ may be provided. According to still another aspect, an inexpensive lithium-ion secondary battery having a high energy density may be provided.

### <Positive Electrode Material for Secondary Batteries>

A positive electrode material for secondary batteries according to the embodiment is represented by Li₄₊ₓFe_{4+y}(P₂O₇)₃, where −0.80≤x≤0.60, −0.30≤y≤0.40, and −0.30≤x+y≤0.30. The positive electrode material for secondary batteries has a triclinic crystal structure. The positive electrode material for secondary batteries preferably belongs to Space group P-1.

LiCoO₂ (3.6 to 3.7 V) and LiMn₂O₄ (3.7 to 3.8 V), which are positive electrode materials having a relatively high potential, contain cobalt (Co) and manganese (Mn), respectively, which are expensive elements. Thus, using LiCoO₂ or LiMn₂O₄ as a positive electrode material disadvantageously increases the cost of the positive electrode material. In contrast, using LiFePO₄, which is produced using iron, which is an inexpensive element, as a raw material, as a positive electrode material does not significantly increase the cost of the positive electrode material. However, LiFePO₄ has a lower potential (3.3 to 3.4 V) than LiCoO₂ or LiMn₂O₄.

Accordingly, the inventor conducted extensive studies in order to produce an inexpensive positive electrode material for secondary batteries which has a potential comparable to that of LiCoO₂ (3.6 to 3.7 V) and, consequently, devised a positive electrode material for secondary batteries which is represented by Li₄₊ₓFe_{4+y}(P₂O₇)₃, where −0.80≤x≤0.60, −0.30≤y≤0.40, and −0.30≤x+y≤0.30, and has a triclinic crystal structure. The above-described positive electrode material for secondary batteries is inexpensive since it is composed of Fe, which is an inexpensive element. Furthermore, the positive electrode material for secondary batteries has a potential comparable to that of LiCoO₂ (3.6 to 3.7 V).

In the above composition formula, x ranges −0.80≤x≤0.60, preferably ranges −0.55≤x≤0.50, more preferably ranges −0.25≤x≤0.20, further preferably ranges −0.10≤x≤0.10, and particularly preferably ranges −0.05≤x≤0.05. In the above composition formula, y ranges −0.30≤y≤0.40, preferably ranges −0.25≤y≤0.28, more preferably ranges −0.10≤y≤0.13, further preferably ranges −0.05≤y≤0.05, and particularly preferably ranges −0.03≤y≤0.03. In the above composition formula, x+y ranges −0.30≤x≤+y≤0.30, preferably ranges −0.28≤x+y≤0.25, more preferably ranges −0.13≤x≤+y≤0.10, further preferably ranges −0.05≤x≤+y≤0.05, and particularly preferably ranges −0.03≤x+y≤0.03. The composition formula Li₄₊ₓFe_{4+y}(P₂O₇)₃ represents Li₄Fe₄(P₂O₇)₃ in the case where x=0.00 and y=0.00. Li₄Fe₄(P₂O₇)₃ may be denoted as Li_{5.33}Fe_{5.33}(P₂O₇)₄.

The method for producing the positive electrode material for secondary batteries according to the embodiment is not limited and may be selected appropriately depending on the purpose. It is preferable to use the following method for producing the positive electrode material for secondary batteries.

<Method for Producing Positive Electrode Material for Secondary Batteries>

A method for producing the positive electrode material for secondary batteries according to the embodiment includes a heat treatment step and may optionally include other optional steps, such as a mixing step.

<Mixing Step>

The mixing step may be any step in which a lithium source, an iron source, and a phosphate source are mixed with one another to form a mixture of these materials and may be selected appropriately depending on the purpose. For example, a planetary ball mill may be used in the mixing step.

Examples of the lithium source include a lithium salt. The anion constituting the lithium salt is not limited and may be selected appropriately depending on the purpose. Examples of the anion include a hydroxide ion, a carbonate ion, an oxalate ion, an acetate ion, a nitrate anion, a sulfate anion, a phosphate ion, a fluoride ion, a chloride ion, a bromide ion, and an iodide ion. The above anions may be used alone or in combination of two or more. The lithium salt is not limited and may be selected appropriately depending on the purpose. Examples of the lithium salt include lithium hydroxide (LiOH), lithium carbonate (Li₂CO₃), lithium nitrate (LiNO₃), lithium sulfate (Li₂SO₄), lithium perchlorate (LiClO₄), lithium hexafluorophosphate (LiPF₆), and lithium tetrafluoroborate (LiBF₄). The above lithium salts may be provided in the form of a hydrate or an anhydride. Among the above lithium salts, lithium carbonate and lithium nitrate are preferable since they do not cause any side reaction.

Examples of the iron source include an iron salt. The anion constituting the iron salt is not limited and may be selected appropriately depending on the purpose. Examples of the anion constituting the iron salt include an oxide ion, a carbonate ion, an oxalate ion, an acetate ion, a nitrate anion, a sulfate anion, a phosphate ion, a fluoride ion, a chloride ion, a bromide ion, and an iodide ion. The above anions may be used alone or in combination of two or more. The iron salt is not limited and may be selected appropriately depending on the purpose. Examples of the iron salt include ferrous oxide, iron(II) oxalate, iron(II) nitrate, iron(II) sulfate, and iron(II) chloride. The above iron salts may be provided in the form of a hydrate or an anhydride.

Examples of the phosphate source include phosphoric acid and a phosphate. The cation constituting the phosphate is not limited and may be selected appropriately depending on the purpose. Examples of the cation include an ammonium ion. Examples of the phosphate include ammonium phosphate, ammonium dihydrogen phosphate, and diammonium hydrogen phosphate.

Instead of the above lithium source and the above phosphate source, compounds that serve as a lithium source and a phosphate source, such as lithium phosphate, dilithium hydrogen phosphate, and lithium dihydrogen phosphate, may be used.

The mixing ratio between the lithium source, the iron source, and the phosphate source is not limited and may be selected appropriately depending on the purpose. The mixing ratio between the lithium source, the iron source, and the phosphate source may be set such that, for example, the element ratio Li:Fe:P is 3.2 to 4.6:3.7 to 4.4:6.0.

<Heat Treatment Step>

The heat treatment step may be any step in which the above mixture is heated and may be selected appropriately depending on the purpose.

The temperature at which the heat treatment is performed is not limited and may be selected appropriately depending on the purpose. The heat treatment temperature is preferably 470° C. or higher and 720° C. or lower and is more preferably 500° C. or higher and 650° C. or lower. If the heat treatment temperature is lower than 470° C., the intended crystal structure may fail to be formed. If the heat treatment temperature is higher than 720° C., the product may become fused disadvantageously. The amount of time during which the heat treatment is performed is not limited and may be selected appropriately depending on the purpose. The heat treatment time is preferably 1 hour or more and 24 hours or less, is more preferably 2 hours or more and 18 hours or less, and is particularly preferably 3 hours or more and 15 hours or less. The above-described heat treatment is preferably performed in an inert atmosphere, such as an argon atmosphere.

### <Lithium-Ion Secondary Battery>

A lithium-ion secondary battery according to the embodiment includes at least the positive electrode material for secondary batteries according to the embodiment and may optionally further include other components.

The lithium-ion secondary battery includes the inexpensive positive electrode material for secondary batteries which exhibits a potential comparable to that of LiCoO₂, which exhibits a relatively high potential. The positive electrode material having a high potential increases the energy density of the lithium-ion secondary battery. Consequently, the lithium-ion secondary battery is inexpensive and has a high energy density.

The lithium-ion secondary battery includes, for example, at least a positive electrode and may optionally further include other components, such as a negative electrode, an electrolyte, a separator, a positive electrode casing, and a negative electrode casing.

### <Positive Electrode>

The positive electrode includes at least the positive electrode material for secondary batteries according to the embodiment and may optionally further include other components, such as a positive electrode current collector.

In the positive electrode, the positive electrode material for secondary batteries serves as a “positive electrode active material”. The content of the positive electrode material for secondary batteries in the positive electrode is not limited and may be selected appropriately depending on the purpose. In the positive electrode, the positive electrode material for secondary batteries may be mixed with a conductive material and a binder to form a positive electrode layer. The conductive material is not limited and may be selected appropriately depending on the purpose. Examples of the conductive material include carbon conductive materials, such as acetylene black and carbon black. The binder is not limited and may be selected appropriately depending on the purpose. Examples of the binder include polytetrafluoroethylene (PTFE), polyvinylidene fluoride (PVDF), an ethylene-propylene-butadiene rubber (EPBR), a styrene-butadiene rubber (SBR), and carboxymethyl cellulose (CMC).

The material for the positive electrode and the size and structure of the positive electrode are not limited and may be selected appropriately depending on the purpose. The shape of the positive electrode is not limited and may be selected appropriately depending on the purpose. Examples of the shape of the positive electrode include a rod-like shape and a disc-like shape.

<Positive Electrode Current Collector>

The shape, size, and structure of the positive electrode current collector are not limited and may be selected appropriately depending on the purpose. The material for the positive electrode current collector is not limited and may be selected appropriately depending on the purpose. Examples of the material for the positive electrode current collector include stainless steel, aluminum, copper, and nickel.

The positive electrode current collector provides good electrical conduction between the positive electrode layer and the positive electrode casing, which serves as a terminal.

<Negative Electrode>

The negative electrode includes at least a negative electrode active material and may optionally further include other components, such as a negative electrode current collector.

The size and structure of the negative electrode are not limited and may be selected appropriately depending on the purpose. The shape of the negative electrode is not limited and may be selected appropriately depending on the purpose. Examples of the shape of the negative electrode include a rod-like shape and a disc-like shape.

<Negative Electrode Active Material>

The negative electrode active material is not limited and may be selected appropriately depending on the purpose. Examples of the negative electrode active material include a compound containing an alkali metal element. Examples of forms of the compound containing an alkali metal element include a metal simple substance, an alloy, a metal oxide, and a metal nitride. Examples of the alkali metal element include lithium. Examples of the metal simple substance include lithium. Examples of the alloy include alloys containing lithium, such as a lithium-aluminum alloy, a lithium-tin alloy, a lithium-lead alloy, and a lithium-silicon alloy. Examples of the metal oxide include metal oxides containing lithium, such as lithium titanium oxide. Examples of the metal nitride include metal nitrides containing lithium, such as lithium cobalt nitride, lithium iron nitride, and lithium manganese nitride.

The content of the negative electrode active material in the negative electrode is not limited and may be selected appropriately depending on the purpose.

In the negative electrode, the negative electrode active material may be mixed with a conductive material and a binder to form a negative electrode layer. The conductive material is not limited and may be selected appropriately depending on the purpose. Examples of the conductive material include carbon conductive materials, such as acetylene black and carbon black. The binder is not limited and may be selected appropriately depending on the purpose. Examples of the binder include polytetrafluoroethylene (PTFE), polyvinylidene fluoride (PVDF), an ethylene-propylene-butadiene rubber (EPBR), a styrene-butadiene rubber (SBR), and carboxymethyl cellulose (CMC).

<Negative Electrode Current Collector>

The shape, size, and structure of the negative electrode current collector are not limited and may be selected appropriately depending on the purpose. The material for the negative electrode current collector is not limited and may be selected appropriately depending on the purpose. Examples of the material for the negative electrode current collector include stainless steel, aluminum, copper, and nickel.

The negative electrode current collector provides good electrical conduction between the negative electrode layer and the negative electrode casing, which serves as a terminal.

<Electrolyte>

The electrolyte is not limited and may be selected appropriately depending on the purpose. Examples of the electrolyte include a nonaqueous electrolyte solution and a solid electrolyte.

<Nonaqueous Electrolyte Solution>

Examples of the nonaqueous electrolyte solution include a nonaqueous electrolyte solution containing a lithium salt and an organic solvent.

<Lithium Salt>

The lithium salt is not limited and may be selected appropriately depending on the purpose. Examples of the lithium salt include lithium hexafluorophosphate, lithium tetrafluoroborate, lithium perchlorate, lithium bis(pentafluoroethanesulfone)imide, and lithium bis(trifluoromethanesulfone)imide. The above lithium salts may be used alone or in combination of two or more.

The concentration of the lithium salt is not limited and may be selected appropriately depending on the purpose. The concentration of the lithium salt in the organic solvent is preferably 0.5 to 3 mol/L in consideration of ionic conductivity.

<Organic Solvent>

The organic solvent is not limited and may be selected appropriately depending on the purpose. Examples of the organic solvent include ethylene carbonate, dimethyl carbonate, propylene carbonate, diethyl carbonate, and ethyl methyl carbonate. The above organic solvents may be used alone or in combination of two or more.

The content of the organic solvent in the nonaqueous electrolyte solution is not limited and may be selected appropriately depending on the purpose. The content of the organic solvent in the nonaqueous electrolyte solution is preferably 75% to 95% by mass and is more preferably 80% to 90% by mass. If the content of the organic solvent in the nonaqueous electrolyte solution is less than 75% by mass, the viscosity of the nonaqueous electrolyte solution is high and the wettability of the electrodes with the nonaqueous electrolyte solution is low. In such a case, the internal resistance of the battery may be increased. If the content of the organic solvent in the nonaqueous electrolyte solution is more than 95% by mass, the ionic conductivity of the nonaqueous electrolyte solution is low. In such a case, the power of the battery may be reduced. Setting the content of the organic solvent in the nonaqueous electrolyte solution to fall within the above more preferable range enables a high ionic conductivity to be maintained. Furthermore, an increase in the viscosity of the nonaqueous electrolyte solution may be limited. This enables the wettability of the electrodes with the nonaqueous electrolyte solution to be maintained.

<Solid Electrolyte>

The solid electrolyte is not limited and may be selected appropriately depending on the purpose. Examples of the solid electrolyte include an inorganic solid electrolyte and a solvent-free polymer electrolyte. Examples of the inorganic solid electrolyte include a LISICON material and a perovskite material. Examples of the solvent-free polymer electrolyte include a polymer including an ethylene oxide bond.

The content of the electrolyte in the lithium-ion secondary battery is not limited and may be selected appropriately depending on the purpose.

<Separator>

The material for the separator is not limited and may be selected appropriately depending on the purpose. Examples of a material for the separator include paper, cellophane, polyolefin nonwoven fabric, polyamide nonwoven fabric, and glass fiber nonwoven fabric. Examples of the paper include Kraft paper, vinylon mixed paper, and synthetic pulp mixed paper. The shape of the separator is not limited and may be selected appropriately depending on the purpose. Examples of the shape of the separator include a sheet-like shape. The separator may have a single-layer structure or a multilayer structure. The size of the separator is not limited and may be selected appropriately depending on the purpose.

<Positive Electrode Casing>

The material for the positive electrode casing is not limited and may be selected appropriately depending on the purpose. Examples of the material for the positive electrode casing include copper, stainless steel, and a stainless steel or iron material on which a nickel plating film is deposited. The shape of the positive electrode casing is not limited and may be selected appropriately depending on the purpose. Examples of the shape of the positive electrode casing include a shallow-dish-like shape with edges curled upward, a cylindrical shape with a bottom, and a prism-like shape with a bottom. The positive electrode casing may have a single-layer structure or a multilayer structure. Examples of the multilayer structure include a three-layer structure constituted by a nickel layer, a stainless steel layer, and a copper layer. The size of the positive electrode casing is not limited and may be selected appropriately depending on the purpose.

<Negative Electrode Casing>

The material for the negative electrode casing is not limited and may be selected appropriately depending on the purpose. Examples of the material for the negative electrode casing include copper, stainless steel, and a stainless steel or iron material on which a nickel plating film is deposited. The shape of the negative electrode casing is not limited and may be selected appropriately depending on the purpose. Examples of the shape of the negative electrode casing include a shallow-dish-like shape with edges curled upward, a cylindrical shape with a bottom, and a prism-like shape with a bottom. The negative electrode casing may have a single-layer structure or a multilayer structure. Examples of the multilayer structure include a three-layer structure constituted by a nickel layer, a stainless steel layer, and a copper layer. The size of the negative electrode casing is not limited and may be selected appropriately depending on the purpose.

The shape of the lithium-ion secondary battery is not limited and may be selected appropriately depending on the purpose. Examples of the shape of the lithium-ion secondary battery include a coin-like shape, a cylindrical shape, a rectangular shape, and a sheet-like shape.

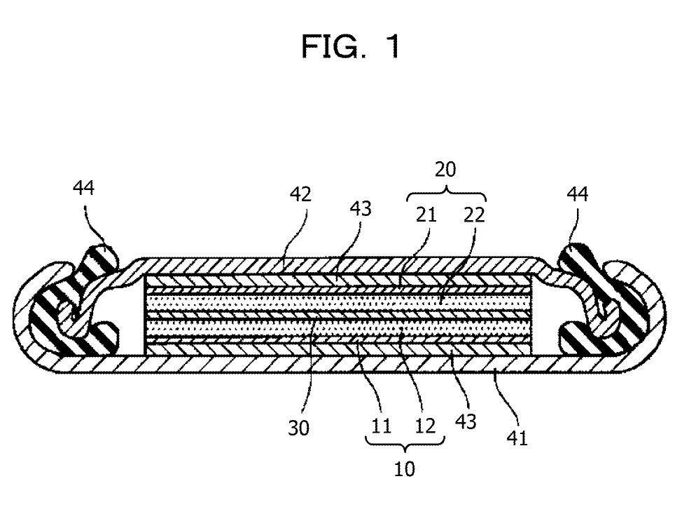

An example of the lithium-ion secondary battery according to the embodiment is described below with reference to FIG. 1. FIG. 1 is a schematic cross-sectional view of an example of the lithium-ion secondary battery according to the embodiment. The lithium-ion secondary battery illustrated in FIG. 1 is a coin-shaped lithium-ion secondary battery. The coin-shaped lithium-ion secondary battery includes a positive electrode 10 constituted by a positive electrode current collector 11 and a positive electrode layer 12, a negative electrode 20 constituted by a negative electrode current collector 21 and a negative electrode layer 22, and an electrolyte layer 30 interposed between the positive electrode 10 and the negative electrode 20. In the lithium-ion secondary battery illustrated in FIG. 1, the positive electrode current collector 11 is fixed to a positive electrode casing 41 with a current collector 43 interposed therebetween, and the negative electrode current collector 21 is fixed to a negative electrode casing 42 with a current collector 43 interposed therebetween. A gasket 44 composed of polypropylene or the like is interposed between the positive electrode casing 41 and the negative electrode casing 42 in order to seal the battery. The current collectors 43 provide electrical conduction between the positive electrode current collector 11 and the positive electrode casing 41 and between the negative electrode current collector 21 and the negative electrode casing 42 while filling the gaps therebetween. The positive electrode layer 12 is prepared using the positive electrode material for secondary batteries according to the embodiment.

### EXAMPLES

Examples of the technology according to the embodiment are described below. The technology according to the embodiment is not limited to Examples below. The raw materials used in Examples and Comparative examples below were available from the companies below.

Li₂CO₃: Kojundo Chemical Laboratory Co., Ltd.

FeC₂O₄·2H₂O: JUNSEI CHEMICAL CO., LTD.

(NH₄)₂HPO₄: KANTO CHEMICAL CO., INC.

Li₄P₂O₇: Toshima Manufacturing Co., Ltd.

Fe₂P₂O₇: Toshima Manufacturing Co., Ltd.

### Example 1

Preparation of Positive Electrode Material for Secondary Batteries

Into a container of a planetary ball mill, 1.48 g of Li₂CO₃, 7.20 g of FeC₂O₄·2H₂O, and 7.92 g of (NH₄)₂HPO₄ were charged. Subsequently, the container of a planetary ball mill was placed in a ball mill. The ball mill was driven in order to mix the raw materials with one another. The resulting mixture was fired at 600° C. for 6 hours in an argon atmosphere. Hereby, Li_{5.33}Fe_{5.33}(P₂O₇)₄, which is a positive electrode material, was prepared.

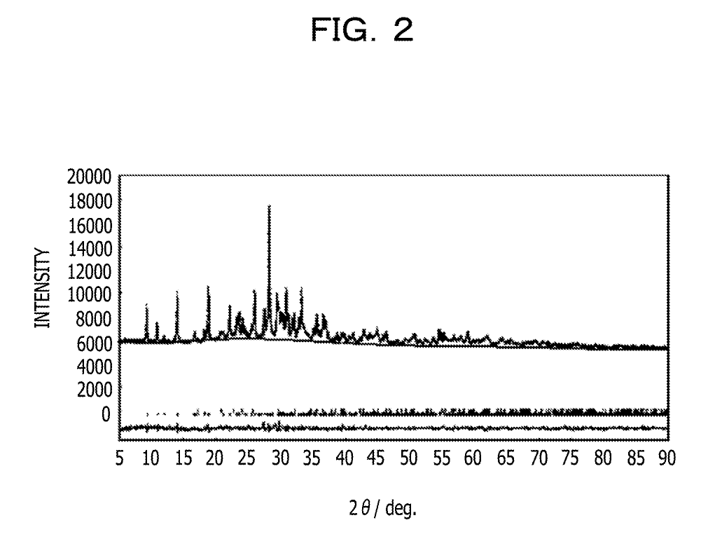

FIG. 2 illustrates an XRD spectrum (by Cu-Kα X-ray) of the substance prepared above. The presence of the diffraction peaks confirmed that the substance had a crystal structure. The results of a Rietveld analysis confirmed that the substance had a triclinic crystal phase and belonged to Space group P-1 (No. 2). The crystal structure had the following lattice constants.

a=6.34 Å

b=8.50 Å

c=9.95 Å

α=107.9°

β=89.82°

γ=93.02°

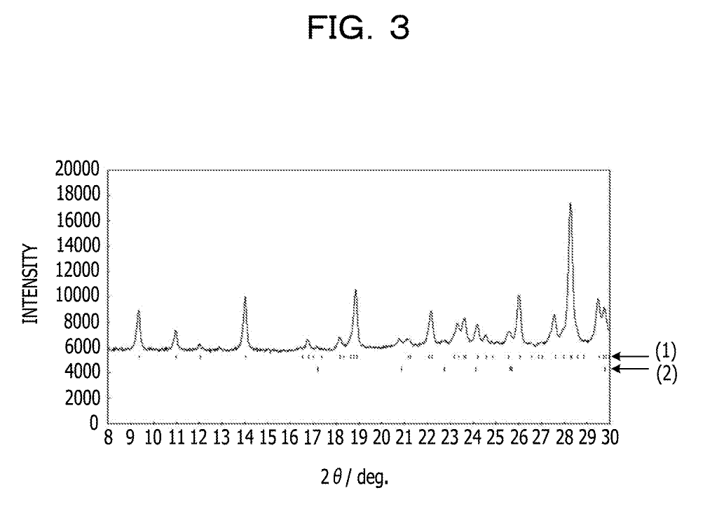

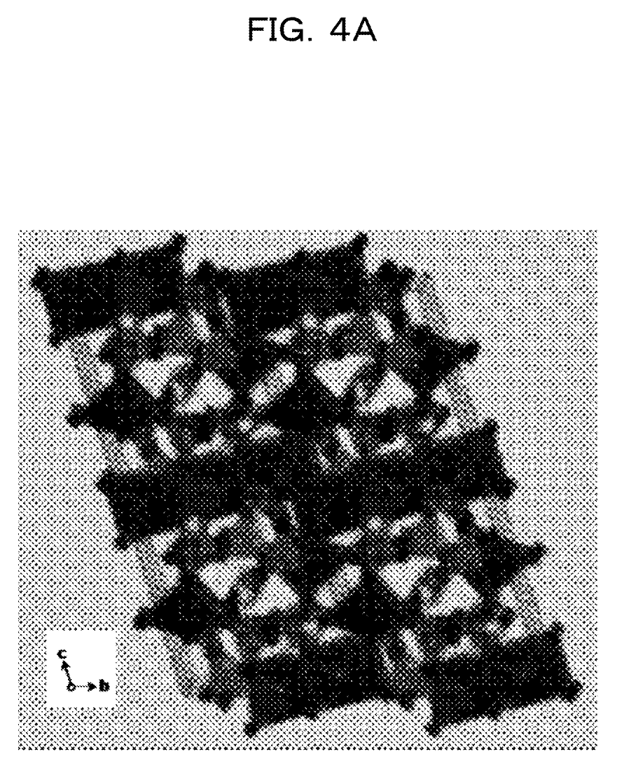

The substance had a purity of 96% by mass. As an impurity phase, diffraction peaks resulting from LiFePO₄ (4 mass %) were detected. FIG. 3 and Table 1 describe the results of indexing of the diffraction peaks at lower angles. FIG. 4 (i.e., FIGS. 4A and 4B) illustrates the appearance of the crystal structure. Table 2 describes the crystal structure parameters. In FIG. 3, (1) denotes the 20 values of the diffraction peaks resulting from Li_{5.33}Fe_{5.33}(P₂O₇)₄ (triclinic) and (2) denotes the 2θ values of the diffraction peaks resulting from LiFePO₄.

TABLE 1

| 2θ/deg. | d/Å | h | k | l |
|---|---|---|---|---|
| 9.38 | 9.473 | 0 | 0 | 1 |
| 11.00 | 8.078 | 0 | 1 | 0 |
| 12.06 | 7.365 | 0 | 1 | −1 |
| 14.05 | 6.326 | 1 | 0 | 0 |
| 16.51 | 5.384 | 0 | 1 | 1 |
| 16.80 | 5.294 | 1 | 0 | −1 |
| 17.01 | 5.228 | 1 | 0 | 1 |
| 17.38 | 5.117 | 1 | −1 | 0 |
| 18.18 | 4.894 | 1 | −1 | 1 |
| 18.33 | 4.854 | 1 | 1 | 0 |
| 18.63 | 4.776 | 0 | 1 | −2 |
| 18.79 | 4.736 | 0 | 0 | 2 |
| 18.90 | 4.709 | 1 | 1 | −1 |
| 21.15 | 4.212 | 0 | 2 | −1 |
| 21.25 | 4.192 | 1 | −1 | −1 |
| 22.06 | 4.039 | 0 | 2 | 0 |
| 22.20 | 4.014 | 1 | 1 | 1 |
| 23.19 | 3.846 | 1 | −1 | 2 |
| 23.36 | 3.817 | 1 | 0 | −2 |
| 23.60 | 3.779 | 1 | 1 | −2 |
| 23.68 | 3.767 | 1 | 0 | 2 |
| 24.23 | 3.683 | 0 | 2 | −2 |
| 24.60 | 3.628 | 0 | 1 | 2 |
| 24.86 | 3.591 | 1 | −2 | 1 |
| 25.57 | 3.491 | 1 | −2 | 0 |
| 26.06 | 3.427 | 1 | 2 | −1 |
| 26.58 | 3.361 | 0 | 2 | 1 |
| 26.89 | 3.323 | 1 | 2 | 0 |
| 27.04 | 3.306 | 0 | 1 | −3 |
| 27.61 | 3.238 | 1 | −2 | 2 |
| 27.98 | 3.196 | 1 | −1 | −2 |
| 28.28 | 3.163 | 2 | 0 | 0 |
| 28.33 | 3.158 | 0 | 0 | 3 |
| 28.58 | 3.130 | 1 | 2 | −2 |
| 28.86 | 3.101 | 1 | 1 | 2 |
| 29.53 | 3.032 | 1 | −2 | −1 |
| 29.72 | 3.013 | 2 | 0 | −1 |
| 29.84 | 3.001 | 2 | −1 | 0 |
| 29.98 | 2.988 | 2 | 0 | 1 |

TABLE 2

| | | | x | y | z | Occ. | U | Site | Sym. |
|---|---|---|---|---|---|---|---|---|---|
| 1 | Fe | Fe5 | 0.5 | 0.5 | 0 | 0.922 | 0.01 | 1e | −1 |
| 2 | Fe | Fe6 | 0.6499 | 0.1196 | −0.0601 | 0.976 | 0.01 | 2i | 1 |
| 3 | Fe | Fe7 | 0.3142 | 0.8887 | 0.6479 | 0.963 | 0.01 | 2i | 1 |
| 4 | P | P1 | 0.529 | 0.2447 | 0.685 | 1 | 0.011 | 2i | 1 |
| 5 | P | P2 | 0.149 | 0.214 | 0.0189 | 1 | 0.011 | 2i | 1 |
| 6 | P | P3 | 0.266 | 0.54 | 0.7383 | 1 | 0.011 | 2i | 1 |
| 7 | P | P4 | 0.185 | 0.193 | 0.3169 | 1 | 0.011 | 2i | 1 |
| 8 | Li | Li1 | 0.03 | 0.192 | 0.661 | 0.854 | 0.12 | 2i | 1 |
| 9 | Fe | Fe1 | 0.03 | 0.192 | 0.661 | 0.146 | 0.01 | 2i | 1 |
| 10 | Li | Li2 | 0.5 | 0.5 | 0.5 | 1 | 0.12 | 1h | −1 |
| 11 | Li | Li3 | −0.08 | 0.348 | 0.842 | 1 | 0.12 | 2i | 1 |
| 12 | Li | Li4 | 0 | 0.5 | 0.5 | 0.625 | 0.12 | 1g | −1 |
| 13 | Fe | Fe4 | 0 | 0.5 | 0.5 | 0.242 | 0.01 | 1g | −1 |
| 14 | O | O1 | 0.237 | 0.373 | 0.413 | 1 | 0.007 | 2i | 1 |
| 15 | O | O2 | 0.46 | 0.419 | 0.665 | 1 | 0.007 | 2i | 1 |
| 16 | O | O3 | 0.228 | 0.384 | 0.025 | 1 | 0.007 | 2i | 1 |
| 17 | O | O4 | −0.042 | 0.16 | −0.081 | 1 | 0.007 | 2i | 1 |
| 18 | O | O5 | 0.643 | −0.092 | 0.739 | 1 | 0.007 | 2i | 1 |
| 19 | O | O6 | 0.383 | 0.711 | 0.181 | 1 | 0.007 | 2i | 1 |
| 20 | O | O7 | −0.014 | −0.082 | 0.635 | 1 | 0.007 | 2i | 1 |
| 21 | O | O8 | 0.323 | 0.085 | −0.027 | 1 | 0.007 | 2i | 1 |
| 22 | O | O9 | 0.329 | 0.132 | 0.652 | 1 | 0.007 | 2i | 1 |
| 23 | O | O10 | 0.072 | 0.426 | 0.72 | 1 | 0.007 | 2i | 1 |
| 24 | O | O11 | 0.295 | 0.799 | 0.432 | 1 | 0.007 | 2i | 1 |
| 25 | O | O12 | −0.089 | 0.818 | 0.832 | 1 | 0.007 | 2i | 1 |
| 26 | O | O13 | 0.314 | 0.634 | 0.886 | 1 | 0.007 | 2i | 1 |
| 27 | O | O14 | 0.274 | 0.646 | 0.646 | 1 | 0.007 | 2i | 1 |

### Example 2

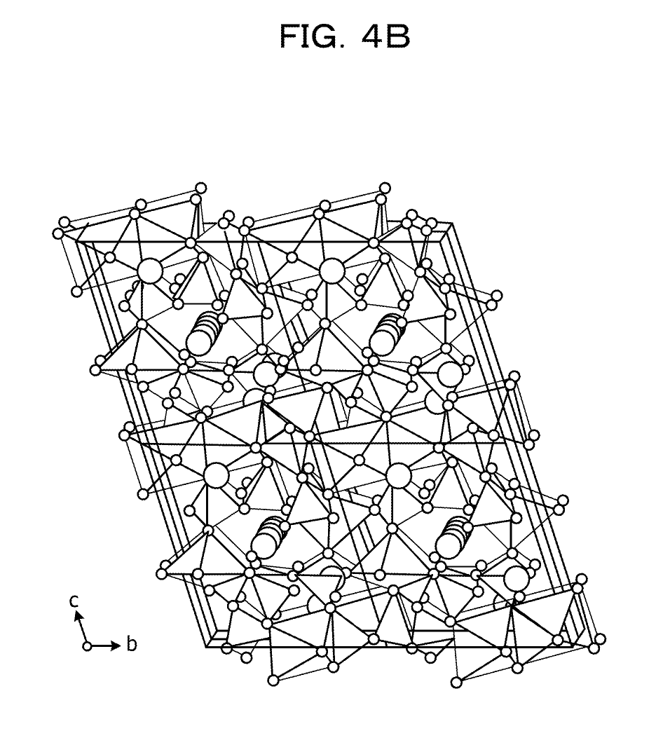

Changes in the XRD spectrum of the positive electrode material which occurred when the Fe and Li contents were changed from those in Example 1 were determined. FIG. 5 illustrates the results. The arrows illustrated in FIG. 5 indicate the diffraction peaks resulting from impurities. The XRD spectra illustrated in FIG. 5 correspond to the following substances from top to bottom.

(3): Li_{6.0}Fe_{5.0}(P₂O₇)₄ [Li_{4.50}Fe_{3.75}(P₂O₇)₃]

(4): Li_{5.6}Fe_{5.2}(P₂O₇)₄ [Li_{4.20}Fe_{3.90}(P₂O₇)₃]

(5): Li_{5.33}Fe_{5.33}(P₂O₇)₄ [Li_{4.00}Fe_{4.00}(P₂O₇)₃]

(6): Li_{5.0}Fe_{5.5}(P₂O₇)₄ [Li_{3.75}Fe_{4.13}(P₂O₇)₃]

(7): Li_{4.6}Fe_{5.7}(P₂O₇)₄ [Li_{3.45}Fe_{4.28}(P₂O₇)₃]

The results illustrated in FIG. 5 confirm that a positive electrode material having a composition of Li_{5.33}Fe_{5.33}(P₂O₇)₄ had the highest purity. Li_{5.6}Fe_{5.2}(P₂O₇)₄ had the second lowest impurity content next to Li_{5.33}Fe_{5.33}(P₂O₇)₄.

Table 3 summarizes the results.

TABLE 3

| | | Relative to (P₂O₇)₃ | | | |
|---|---|---|---|---|---|
| | | Li | Fe | Li + Fe | (Li + Fe) − 8.00 |
| (3) | Li_{6.0}Fe_{5.0}(P₂O₇)₄[Li_{4.50}Fe_{3.75}(P₂O₇)₃] | 4.50 | 3.75 | 8.25 | 0.25 |
| (4) | Li_{5.6}Fe_{5.2}(P₂O₇)₄[Li_{4.20}Fe_{3.90}(P₂O₇)₃] | 4.20 | 3.90 | 8.10 | 0.10 |
| (5) | Li_{5.33}Fe_{5.33}(P₂O₇)₄[Li_{4.00}Fe_{4.00}(P₂O₇)₃] | 4.00 | 4.00 | 8.00 | 0.00 |
| (6) | Li_{5.0}Fe_{5.5}(P₂O₇)₄[Li_{3.75}Fe_{4.13}(P₂O₇)₃] | 3.75 | 4.13 | 7.88 | −0.13 |
| (7) | Li_{4.6}Fe_{5.7}(P₂O₇)₄[Li_{3.45}Fe_{4.28}(P₂O₇)₃] | 3.45 | 4.28 | 7.73 | −0.28 |

The three-digit numbers described in the columns of “Li” and “Fe” in Table 3 are calculated by performing rounding to two decimal places.

### Comparative Example 1

Li₄P₂O₇ having a crystal structure and Fe₂P₂O₇ having a crystal structure were weighed in certain amounts such that the molar ratio of Li₄P₂O₇ to Fe₂P₂O₇ (Li₄P₂O₇:Fe₂P₂O₇) was 1:2 and mixed with each other in a mortar to form a substance having a composition of Li_{5.33}Fe_{5.33}(P₂O₇)₄ as a whole.

It was confirmed that the substance had a crystal structure because diffraction peaks were detected in the XRD analysis of the substance. It was also confirmed that the substance was a mixture of a Li₄P₂O₇ crystal phase (JCPDS card No. 01-077-0145) and a Fe₂P₂O₇ crystal phase (JCPDS card No. 01-076-1762) as a result of the identification of crystal phases from the diffraction peak positions.

### Example 3

### <Preparation of Half Cell>

A Half cell was prepared using the positive electrode material, that is, the positive electrode active material, prepared in Example 1. The positive electrode used was prepared using an electrode mixture containing the positive electrode active material, conductive carbon (KETJENBLACK, ECP600JD produced by Lion Specialty Chemicals Co., Ltd.), and polyvinylidene fluoride (KF#1300 produced by KUREHA CORPORATION) at a mass ratio (positive electrode active material:conductive carbon:polyvinylidene fluoride) of 85:10:5. The electrolyte solution used was an electrolyte solution produced by KISHIDA CHEMICAL Co., Ltd., which was prepared by dissolving 1 M of lithium hexafluorophosphate (LiPF₆) in a mixed solvent containing ethylene carbonate (EC) and dimethyl carbonate (DMC) at a volume ratio EC:DMC of 1:2. The negative electrode used was composed of metal lithium.

### <Constant-Current Charge/Discharge Test>

The half cell was subjected to a constant-current charge/discharge test under the following conditions. The charge of the half cell and the discharge of the half cell were terminated when a specific voltage was reached; the charge of the half cell was terminated when the voltage reached 4.5 V, and the discharge of the half cell was terminated when the voltage reached 2.0 V. An interval of 10 minutes was placed between each pair of charging and discharging in an open-circuit state.

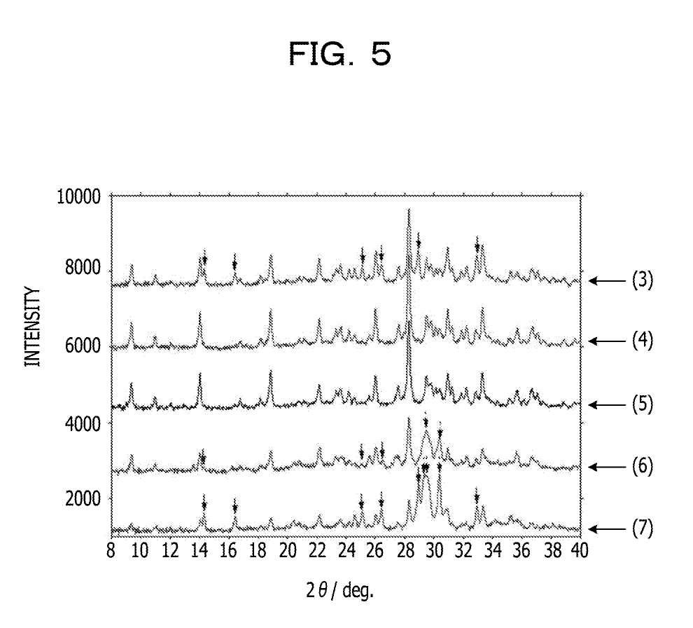

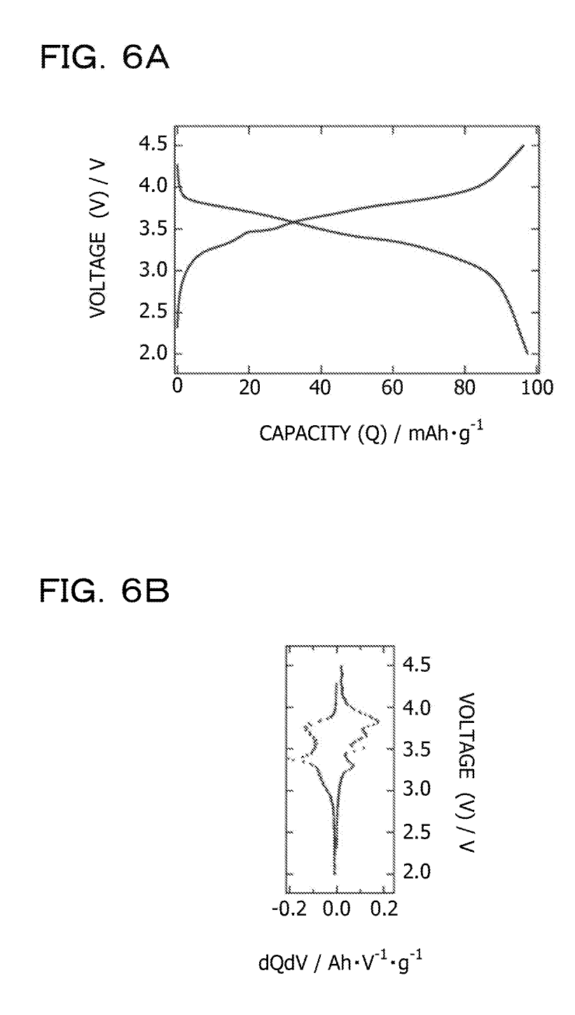

The half cell had charge and discharge capacities of about 100 mAh/g. FIG. 6A illustrates the constant-current charge/discharge curve of the half cell. FIG. 6B illustrates a dQ/dV plot derived from the charge/discharge curve. The peaks of the dQ/dV plot represent plateau regions included in the charge/discharge curve. Among the peaks of the charging curve, the highest voltage of the plateau regions was 3.81 V. Among the peaks of the discharging curve, the highest voltage of the plateau regions was 3.77 V. This confirmed that the positive electrode material prepared in Example 1 had an average voltage of 3.79 V at maximum.

### Comparative Example 2

### <Preparation and Constant-Current Charge/Discharge Test of Half Cell>

A half cell was prepared as in Example 3, except that the positive electrode material used in Example 3 was changed to the substance prepared in Comparative example 1. The half cell was subjected to a constant-current charge/discharge test as in Example 3. The results of the charge/discharge test confirmed that the charge and discharge capacities of the half cell were insignificant (<0.1 mAh/g).

The results of Example 3 and Comparative example 2 confirmed that a high potential of 3.8 V may be achieved when the positive electrode material not only satisfies Li₄₊ₓFe_{4+y}(P₂O₇)₃, where −0.80≤x≤0.60, −0.30≤y≤0.40, and −0.30≤x+y≤0.30, but also has a triclinic crystal structure. For example, although a material represented by Li_{5.33}Fe_{5.33}(P₂O₇)₄ was prepared by mixing Li₄P₂O₇ and Fe₂P₂O₇ having a crystal structure with each other at a molar ratio of 1:2, the material did not have a high potential of 3.8 V.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A positive electrode material for secondary batteries,
the positive electrode material being represented by Li₄₊ₓFe_{4+y}(P₂O₇)₃, where −0.80≤x≤0.60, −0.30≤y≤0.40, and −0.30≤x+y≤0.30,
the positive electrode material comprising a triclinic crystal structure.

2. The positive electrode material for secondary batteries according to claim 1,
wherein the crystal structure belongs to Space group P-1.

3. A method for producing a positive electrode material for secondary batteries, in which the positive electrode material for secondary batteries according to claim 1 is produced, the method comprising:
heating a mixture of a lithium source, an iron source, and a phosphate source.

4. The method for producing a positive electrode material for secondary batteries according to claim 3,
wherein the heating is performed at 470° C. or more and 720° C. or less.

5. The method for producing a positive electrode material for secondary batteries according to claim 3,
wherein the heating is performed in an inert atmosphere.

6. A lithium-ion secondary battery comprising:
a positive electrode including the positive electrode material for secondary batteries according to claim 1;
a negative electrode; and
an electrolyte.
